(19) United States
(12) Patent Application Publication
(10) Pub. No.: US 2011/0126905 A1
(43) Pub. Date: Jun. 2, 2011

(54) DYE-SENSITIZED SOLAR CELL INCLUDING SPACERS

(76) Inventors: Nam-Choul Yang, Suwon-si (KR); Sung-Su Kim, Suwon-si (KR); Byong-Cheol Shin, Suwon-si (KR)

(21) Appl. No.: 12/789,206

(22) Filed: May 27, 2010

(30) Foreign Application Priority Data
Nov. 30, 2009 (KR) 10-2009-0117072

(51) Int. Cl. H01L 31/00

(52) U.S. Cl. 136/261

(57) ABSTRACT

A dye-sensitized solar cell is disclosed. The dye-sensitized solar cell includes a plurality of spacers disposed between a photoelectrode and a counter electrode to maintain a uniform distance between the photoelectrode and the counter electrode. First ends of the plurality of spacers are melted and fixed to the counter electrode. The counter electrode includes a grid, a protective layer is formed on the grid, and the first ends of the plurality of spacers are fixed (or thermally fixed) to the protective layer.

### CROSS-REFERENCE TO RELATED APPLICATION

This application claims priority to and the benefit of Korean Patent Application No. 10-2009-0117072, filed on Nov. 30, 2009, in the Korean Intellectual Property Office, the entire content of which is incorporated herein by reference.

### BACKGROUND

1. Field

One or more embodiments of the present invention relate to a dye-sensitized solar cell including spacers.

2. Description of Related Art

Extensive research has recently been conducted on solar cells that convert the energy of sunlight into electric energy. Solar cells have attracted attention as an alternative to fossil fuel energy sources.

Various types of solar cells having various working principles have been researched. Currently, wafer-based silicon or crystalline solar cells using a p-n semiconductor junction have appeared to be the most prevalent. However, the manufacturing costs of the wafer-based silicon or crystalline solar cells are high because they are formed of a high purity semiconductor material.

Unlike wafer-based silicon or crystalline solar cells, dye-sensitized solar cells include a photosensitive dye that receives visible light and generates excited electrons, a semiconductor material that transports the excited electrons, and an electrolyte that reacts with electrons returning from an external circuit. Dye-sensitized solar cells may be manufactured to have large areas for use in large area solar cell modules at relatively low costs.

### SUMMARY

An aspect of an embodiment of the present invention is directed toward a dye-sensitized solar cell including spacers which may be used in a large area module.

Additional aspects will be set forth in part in the description which follows and, in part, will be apparent from the description, or may be learned by practice of the presented embodiments.

According to an embodiment of the present invention, a dye-sensitized solar cell includes: a photoelectrode and a counter electrode facing each other; a semiconductor layer on the photoelectrode and onto which a photosensitive dye configured to be excited by light is adsorbed; a plurality of spacers between the photoelectrode and the counter electrode to maintain a uniform distance between the photoelectrode and the counter electrode; and an electrolyte filled in a space between the photoelectrode and the counter electrode, wherein first ends of the plurality of spacers are melted and fixed to the counter electrode.

In one embodiment, the counter electrode includes a first transparent conductive layer and further includes a catalyst layer and a first grid on the first transparent conductive layer, a first protective layer is on the counter electrode to cover the first grid, and the first ends of the plurality of spacers are melted and fixed to the first protective layer. In one embodiment, the photoelectrode includes a second transparent conductive layer and a second grid on the second transparent conductive layer, and second ends of the plurality of spacers face the second grid. In one embodiment, the second ends of the plurality of spacers are spaced apart from the photoelectrode, and/or the second ends of the plurality of spacers are free ends. In one embodiment, a second protective layer is formed on the second transparent conductive layer to cover the second grid, and a width of at least one of the second ends of the plurality of spacers is less than or equal to a sum of a line width of the second grid and both line widths of the second protective layer at both sides of the second grid.

In one embodiment, the plurality of spacers are composed of a resin selected from the ground consisting of a silicon resin, a polyolefin resin, an ethylene-vinyl acetate resin, an ethylene acrylate resin, and combinations thereof. In one embodiment, the plurality of spacers further include an inorganic filler.

In one embodiment, the plurality of spacers have a height of about 10 μm to about 200 μm.

In one embodiment, each of the plurality of spacers has a bar-shape.

According to an embodiment of the present invention, a dye-sensitized solar cell includes: a photoelectrode including a first grid; a counter electrode including a second grid facing the first grid; a semiconductor layer on the photoelectrode and onto which a photosensitive dye configured to be excited by light is adsorbed; a spacer on the counter electrode to cover the second grid, the spacer including a plurality of protrusions projecting from the second grid toward the first grid to maintain a uniform distance between the photoelectrode and the counter electrode; and an electrolyte filled in a space between the photoelectrode and the counter electrode.

In one embodiment, the spacer further includes a first portion configured as a protective layer on the second grid, the first portion being integrally provided with a corresponding one of the protrusions.

In one embodiment, the photoelectrode further includes a first transparent conductive layer, the first grid being on the first transparent conductive layer, and ends of the protrusions face the first grid. In one embodiment, the ends of the protrusions are spaced apart from the photoelectrode. In one embodiment, a protective layer is on the first transparent conductive layer to cover the first grid, and a width of one of the ends of the plurality of spacers is less than or equal to a sum of a line width of the first grid and both line widths of the protective layer at both sides of the first grid.

In one embodiment, the plurality of spacers are composed of a resin selected from the group consisting of a silicon resin, a polyolefin resin, an ethylene-vinyl acetate resin, an ethylene acrylate resin, and combinations thereof. In one embodiment, the plurality of spacers further comprise an inorganic filler.

In one embodiment, the protrusions have a height of about 10 μm to about 200 μm.

In one embodiment, each of the protrusions has a bar-shape.

According to an embodiment of the present invention, a dye-sensitized solar cell includes: a photoelectrode and a counter electrode facing each other; a semiconductor layer on the photoelectrode and onto which a photosensitive dye excited by light is adsorbed; a plurality of spacers between the photoelectrode and the counter electrode to maintain a uniform distance between the photoelectrode and the counter electrode; and an electrolyte filled in a space between the photoelectrode and the counter electrode, wherein the plurality of spacers have first ends facing and thermally fixed to the counter electrode and second ends facing and non-thermally fixed to the photoelectrode.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of a dye-sensitized solar cell according to an embodiment of the present invention;

FIG. 2 is an enlarged view illustrating a part of the dye-sensitized solar cell of FIG. 1;

FIG. 3 is a plan view of the dye-sensitized solar cell of FIG. 1;

FIG. 4 is a cross-sectional view of a dye-sensitized solar cell according to another embodiment of the present invention; and

FIG. 5 is a plan view of the dye-sensitized solar cell of FIG. 4.

### DETAILED DESCRIPTION

Reference will now be made in more detail to embodiments, which are illustrated in the accompanying drawings. The thicknesses of layers or regions illustrated in the drawings may be exaggerated for clarity. Like reference numerals denote like elements. Like elements are denoted by like reference numerals, and a repeated explanation thereof may not be provided again.

FIG. 1 is a cross-sectional view of a dye-sensitized solar cell 100 according to an embodiment of the present invention.

Referring to FIG. 1, a photoelectrode 114 is formed on a light receiving substrate 110, and a counter electrode 124 is formed on a counter substrate 120. Here, the photoelectrode 114 and the counter electrode 124 are disposed to face each other. A semiconductor layer 118 is formed on the photoelectrode 114, and a photosensitive dye excited by light VL is adsorbed on the semiconductor layer 118.

A sealing member 130 is disposed between the light receiving substrate 110 and the counter substrate 120 so that the light receiving substrate 110 and the counter substrate 120 are adhered to each other with a set or predetermined interval therebetween. An electrolytic solution used to form an electrolytic layer 150 may be filled in a space between the light receiving substrate 110 and the counter substrate 120.

The photoelectrode 114 and the counter electrode 124 are electrically connected to an external circuit 180 through a conductive wire 160. In a dye-sensitized solar cell module in which a plurality of dye-sensitized solar cells are connected to one another in series or in parallel, respective photoelectrodes and counter electrodes of the plurality of dye-sensitized solar cells may be connected in series or in parallel, and the photoelectrode and the counter electrode on either end (or both ends) of the dye-sensitized solar cell module may be connected to the external circuit 180.

The light receiving substrate 110 may be formed of a material having a relatively high light transmittance. For example, the light receiving substrate 110 may be a glass substrate or a resin film substrate. Since a resin film usually has a suitably high flexibility, the resin film may be applied to devices requiring flexibility. The counter substrate 120 does not necessarily have to be transparent. However, in order to improve photoelectric conversion efficiency, the counter substrate 120 may be formed of a transparent material so that the light VL may pass through both sides of the dye-sensitized solar cell 100, and may be formed of the same material as that of the light receiving substrate 110. In particular, if the dye-sensitized solar cell 100 is installed as a building integrated photovoltaic (BIPV) system in a structure, e.g., a window frame, both sides of the dye-sensitized solar cell 100 may be transparent so that the light VL introduced into a building is not substantially blocked by the dye-sensitized solar cell 100.

The photoelectrode 114 may include a transparent conductive layer 111 and a grid (or grids) 112 formed on the transparent conductive layer 111. The transparent conductive layer 111 may be formed of a material having transparency and electrical conductivity such as indium tin oxide (ITO), fluorine tin oxide (FTO), or antimony tin oxide (ATO). The grid 112 electrically contacts the transparent conductive layer 111 and compensates for the relatively low electrical conductivity of the transparent conductive layer 111. For example, the grid 112 may be formed of a metal material having high electrical conductivity, such as gold (Au), silver (Ag), or aluminium (Al), and may be formed to have a mesh pattern.

Since the light VL incident through the photoelectrode 114 excites the photosensitive dye adsorbed onto the semiconductor layer 118, photoelectric conversion efficiency may be improved when the amount of the light VL incident through the photoelectrode 114 is increased. For example, an aperture ratio is a ratio of an effective light transmitting area to the overall area of the light receiving substrate 110 on which the photoelectrode 114 is formed. Since the grid 112 is formed of an opaque material, e.g., a metal material, the aperture ratio decreases as the area of the grid 112 increases. Since a line width of the grid 112 limits the effective light transmitting area, the line width of the grid 112 needs to be small.

A protective layer 115 may be further formed on a surface of the grid 112. The protective layer 115 prevents or protects the grid 112 from being damaged, for example, from being eroded or corroded by the electrolyte layer 150. The protective layer 115 may be formed of a material that does not react with the electrolyte layer 150, for example, a curable resin material.

The semiconductor layer 118 may be formed of a metal oxide composed of a metal, such as cadmium (Cd), zinc (Zn), indium (In), lead or plumbum (Pb), molybdenum (Mo), tungsten (W), antimony or stibium (Sb), titanium (Ti), silver (Ag), manganese (Mn), tin or stannum (Sn), zirconium (Zr), strontium (Sr), gallium (Ga), silicon (Si), and/or chromium (Cr). The semiconductor layer 118 may improve photoelectric conversion efficiency by adsorbing the photosensitive dye. For example, the semiconductor layer 118 may be formed by coating a paste of semiconductor particles having a particle diameter of about 5 nm to about 1000 nm (or 5 nm to 1000 nm) on the conductive layer 111 of the light receiving substrate 110 and applying heat or pressure to the resultant structure.

The photosensitive dye adsorbed onto the semiconductor layer 118 absorbs the light VL passing through the light receiving substrate 110, so that electrons of the photosensitive dye are excited. The excited electrons are transferred to the conduction band of the semiconductor layer 118, and to the photoelectrode 114 through the semiconductor layer 118, and are discharged out of the dye-sensitized solar cell 100 through the photoelectrode 114, thereby forming a driving current for driving the external circuit 180.

The photosensitive dye may be a liquid type, semi-solid gel type, and/or solid type photosensitive dye. For example, the photosensitive dye adsorbed onto the semiconductor layer 118 may be a ruthenium-based photosensitive dye. The semiconductor layer 118 adsorbing the photosensitive dye may be obtained by dipping the light receiving substrate 110 on which the semiconductor layer 118 is formed in a solution containing the photosensitive dye.

The electrolyte layer 150 may be formed of a redox electrolyte containing reductants and oxidants. The electrolyte layer 150 may be a solid type, gel type, and/or liquid type electrolyte.

The counter electrode 124 may include a transparent conductive layer 121 formed on the counter substrate 120, a catalyst layer 123 formed on the transparent conductive layer 121, and a grid (or grids) 122 formed on the catalyst layer 123. The catalyst layer 123 may be formed to be relatively or suitably thin on the transparent conductive layer 121 so as to allow or expose the transparent conductive layer 121 to be electrically coupled to the grid 122. Alternatively, the grid 122 is formed on the transparent conductive layer 121, and then the catalyst layer 123 may be formed on the transparent conductive layer 121 to cover the grid 122.

The transparent conductive layer 121 may be formed of the same material as that of the transparent conductive layer 111. The catalyst layer 123 may be formed of a material for providing electrons to the electrolyte layer 150, for example, a metal such as platinum (Pt), gold (Au), silver (Ag), copper (Cu), and/or aluminum (Al); a metal oxide such as tin oxide; and/or a carbon-based material such as graphite.

In one embodiment, the grid 122 is directly formed on the catalyst layer 123 to electrically contact the catalyst layer 123, compensates for the relatively low electrical characteristics of the catalyst layer 123, and reduces the resistance of the counter electrode 124. The grid 122 may be formed of the same material as that of the grid 112 of the photoelectrode 114.

A protective layer 125 may be further formed on a surface of the grid 122. The protective layer 125 prevents or protects the grid 122 from being damaged, for example, from being eroded by the electrolyte layer 150. The protective layer 125 may be formed of a material that does not react with the electrolyte layer 150, for example, a curable resin material.

A plurality of spacers 190 are disposed between the photoelectrode 114 and the counter electrode 124 to maintain a uniform distance between the photoelectrode 114 and the counter electrode 124. First ends of the spacers 190 may be suitably bonded to the counter electrode 124. Second ends of the spacers 190 may be free ends. In one embodiment, the first ends of the spacers 190 are melted and fixed to the protective layer 125 formed on the grid 122. When the dye-sensitized solar cell 100 is manufactured, if heat treatment, for example, hot pressing, is performed in order to fix the spacers 190 between the counter electrode 124 and the photoelectrode 114, the semiconductor layer 118 may be physically damaged.

However, since the spacers 190 are suitably bonded only to the counter electrode 124 in FIG. 1, the photoelectrode 114 and the semiconductor layer 118 are prevented or protected from being damaged due to the heat treatment for fixing the spacers 190 to the photoelectrode 114.

The first ends of the spacers 190 are melted and fixed to the counter electrode 124, and the second ends of the spacers 190 face the photoelectrode 114. The second ends of the spacers 190 may contact the photoelectrode 114 or may be spaced apart from the photoelectrode 114 by a set or predetermined gap. The spacers 190 may be formed of a material having a suitable elasticity. The spacers 190 may be composed of a silicon resin, a polyolefin resin, an ethylene-vinyl acetate resin, and/or an ethylene acrylate resin. The spacers 190 may further contain inorganic filler which may give stiffness to the spacers 190.

Each of the spacers 190 may have a height of about 10 μm to about 200 μm (or 10 μm to 200 μm). The height of 10 μm is a lower limit for preventing contact between the photoelectrode 114 and the counter electrode 124, and the height of 200 μm is limited by the gap between the photoelectrode 114 and the counter electrode 124.

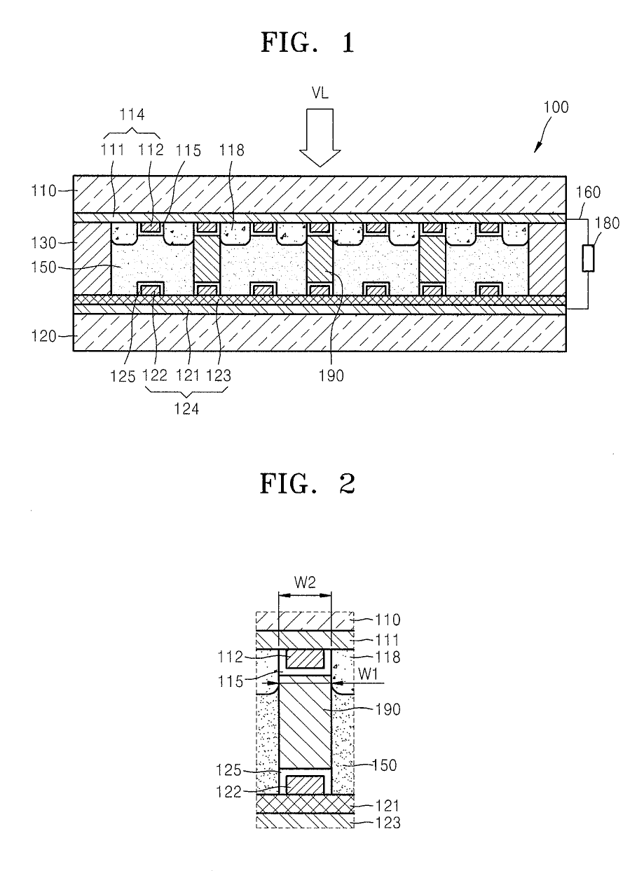

FIG. 2 is an enlarged view illustrating a part of the dye-sensitized solar cell 100 of FIG. 1. A width W1 of the second end of each of the spacers 190 may be less than or equal to a width W2 which is the sum of the line width of the grid 112 and both line widths protective layer 115 at (or adjacent to) both sides of the grid 112 (therebetween) in order to improve photoelectric conversion efficiency without lowering the aperture ratio.

Each of the spacers 190 is bar-shaped or is formed to have a bar shape, so that an electrolyte of the dye-sensitized solar cell 100 circulates in the dye-sensitized solar cell 100 irrespective of the spacers 190.

Although the second ends of the spacers 190 contact the semiconductor layer 118 formed on the photoelectrode 114 in FIGS. 1 and 2, the present embodiment is not limited thereto. The second ends of the spacers 190 may be spaced apart from the semiconductor layer 118 when the light receiving substrate 110 and the counter substrate 120 are attached to each other in the state where the first ends of the spacers 190 are melted and fixed to the counter electrode 124. If the spacers 190 are formed of an elastic material, the second ends of the spacers 190 may contact the semiconductor layer 118 or the photoelectrode 114 and may be partially bent.

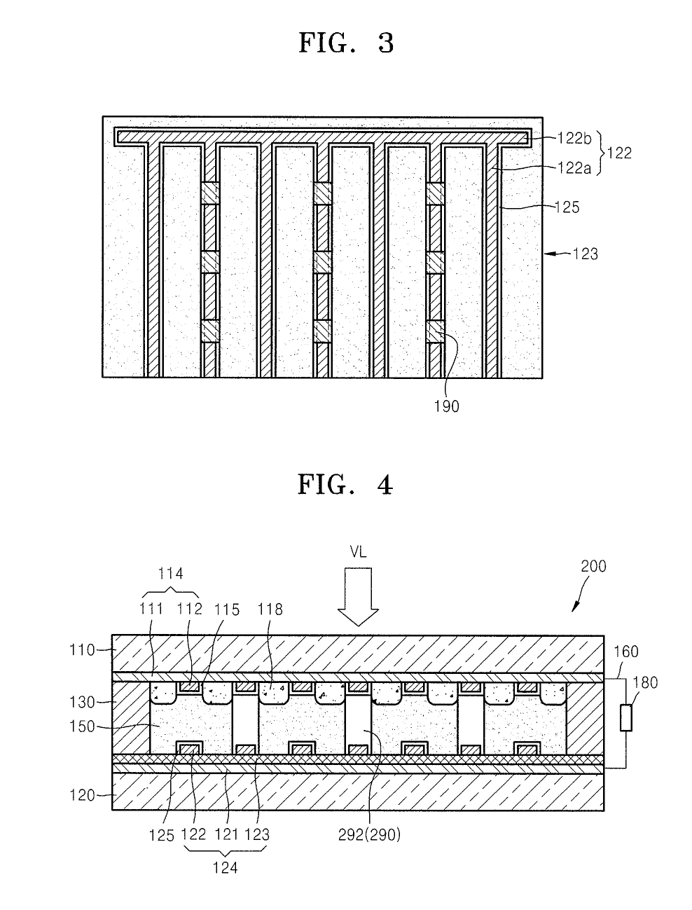

FIG. 3 is a plan view of the dye-sensitized solar cell 100 of FIG. 1. Referring to FIG. 3, the grid 122 includes a plurality of first patterns (or lines) 122a having stripe shapes, and a second pattern (or line) 122b connecting ends of the plurality of first patterns 122a.

The dye-sensitized solar cell 100 of FIG. 1 may be manufactured as a large area solar cell and may maintain a gap between the photoelectrode 114 and the counter electrode 124 by the spacers 190. Also, since the first ends of the spacers 190 are melted and fixed to the counter electrode 124 and the second ends of the spacers 190 facing the photoelectrode 114 are free ends, the photoelectrode 114 and the semiconductor layer 180 may be prevented or protected from being deteriorated during heat treatment when the dye-sensitized solar cell 100 is manufactured.

FIG. 4 is a cross-sectional view of a dye-sensitized solar cell 200 according to another embodiment of the present invention. The same elements as those of the dye-sensitized solar cell 100 of FIG. 1 are denoted by the same reference numerals, and a detailed explanation thereof will not be provided again.

Referring to FIG. 4, a spacer 290 is formed between the photoelectrode 114 and the counter electrode 124 to maintain a uniform distance between the photoelectrode 114 and the counter electrode 124. The spacer 290 covers the grid 122, and includes protrusions 292 which are each projected from the grid 122 toward the corresponding protective layer 115. That is, the spacer 290 may be an integral structure having a first portion corresponding to the protective layer 125, and the first portion is integrally provided with a corresponding one of the protrusions 292, the protrusions 292 corresponding to the spacers 190 of the dye-sensitized solar cell 100 of FIG. 1.

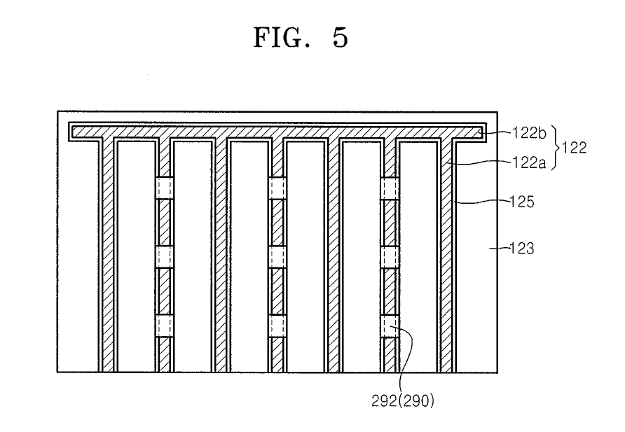

FIG. 5 is a plan view of the dye-sensitized solar cell 200 of FIG. 4. Referring to FIG. 5, the spacer 290 covers the grid 122 and includes the protrusion 292 which is projected from an area of the grid 122.

Referring to FIGS. 4 and 5, second ends of the protrusion 292 are melted and fixed to the counter electrodes 122, and first ends of the protrusions 292 contact the grid (or grids) 112 or are spaced apart from the grid (or girds) 112 at set or predetermined intervals. Each of the protrusions 292 has a width that is equal to or less than a sum of the line width of the grid 112 and both line widths of the protective layer 115 at (or adjacent to) both sides of the grid 112 (therebetween).

The dye-sensitized solar cell 200 of FIG. 4 includes the spacers 290 that project from the counter electrode 124 and act as a protective layer. The dye-sensitized solar cell 200 may be manufactured as a large area solar cell and may maintain a gap between the photoelectrode 114 and the counter electrode 124 by the spacers 290. Also, since the first ends of the spacers 290 are melted and fixed to the counter electrode 124 and the second ends of the spacers 290 facing the photoelectrode 114 are free ends, the photoelectrode 114 and the semiconductor layer 180 may be prevented from being deteriorated during heat treatment when the dye-sensitized solar cell 200 is manufactured.

As described above, according to the one or more of the above embodiments of the present invention, since spacers are only melted and fixed to a counter electrode, contact between the counter electrode and a photoelectrode in a large area module may be prevented. Furthermore, since the spacers are only melted and fixed to the counter electrode, a semiconductor and the photoelectrode layer may be prevented from being deteriorated due to heat treatment to fix the spacers on the photoelectrode layer.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A dye-sensitized solar cell comprising:
a photoelectrode and a counter electrode facing each other;
a semiconductor layer on the photoelectrode and onto which a photosensitive dye configured to be excited by light is adsorbed;
a plurality of spacers between the photoelectrode and the counter electrode to maintain a uniform distance between the photoelectrode and the counter electrode; and
an electrolyte filled in a space between the photoelectrode and the counter electrode,
wherein first ends of the plurality of spacers are melted and fixed to the counter electrode.

2. The dye-sensitized solar cell of claim 1, wherein:
the counter electrode comprises a first transparent conductive layer and further comprises a catalyst layer and a first grid on the first transparent conductive layer,
a first protective layer is on the counter electrode to cover the first grid, and
the first ends of the plurality of spacers are melted and fixed to the first protective layer.

3. The dye-sensitized solar cell of claim 2, wherein:
the photoelectrode comprises a second transparent conductive layer and a second grid on the second transparent conductive layer, and
second ends of the plurality of spacers face the second grid.

4. The dye-sensitized solar cell of claim 3, wherein the second ends of the plurality of spacers are spaced apart from the photoelectrode.

5. The dye-sensitized solar cell of claim 3, wherein the second ends of the plurality of spacers are free ends.

6. The dye-sensitized solar cell of claim 3, wherein:
a second protective layer is formed on the second transparent conductive layer to cover the second grid, and
a width of at least one of the second ends of the plurality of spacers is less than or equal to a sum of a line width of the second grid and both line widths of the second protective layer at both sides of the second grid.

7. The dye-sensitized solar cell of claim 1, wherein the plurality of spacers are composed of a resin selected from the ground consisting of a silicon resin, a polyolefin resin, an ethylene-vinyl acetate resin, an ethylene acrylate resin, and combinations thereof.

8. The dye-sensitized solar cell of claim 7, wherein the plurality of spacers further comprise an inorganic filler.

9. The dye-sensitized solar cell of claim 1, wherein the plurality of spacers have a height of about 10 μm to about 200 μm.

10. The dye-sensitized solar cell of claim 1, wherein each of the plurality of spacers has a bar-shape.

11. A dye-sensitized solar cell comprising:
a photoelectrode comprising a first grid;
a counter electrode comprising a second grid facing the first grid;
a semiconductor layer on the photoelectrode and onto which a photosensitive dye configured to be excited by light is adsorbed;
a spacer on the counter electrode to cover the second grid, the spacer comprising a plurality of protrusions projecting from the second grid toward the first grid to maintain a uniform distance between the photoelectrode and the counter electrode; and
an electrolyte filled in a space between the photoelectrode and the counter electrode.

12. The dye-sensitized solar cell of claim 11, wherein the spacer further comprises a first portion configured as a protective layer on the second grid, the first portion being integrally provided with a corresponding one of the protrusions.

13. The dye-sensitized solar cell of claim 11, wherein the photoelectrode further comprises a first transparent conductive layer, the first grid being on the first transparent conductive layer, and
ends of the protrusions face the first grid.

14. The dye-sensitized solar cell of claim 13, wherein the ends of the protrusions are spaced apart from the photoelectrode.

15. The dye-sensitized solar cell of claim 13, wherein a protective layer is on the first transparent conductive layer to cover the first grid, and
a width of one of the ends of the plurality of spacers is less than or equal to a sum of a line width of the first grid and both line widths of the protective layer at both sides of the first grid.

16. The dye-sensitized solar cell of claim 11, wherein the plurality of spacers are composed of a resin selected from the group consisting of a silicon resin, a polyolefin resin, an ethylene-vinyl acetate resin, an ethylene acrylate resin, and combinations thereof.

17. The dye-sensitized solar cell of claim 16, wherein the plurality of spacers further comprise an inorganic filler.

18. The dye-sensitized solar cell of claim 11, wherein the protrusions have a height of about 10 μm to about 200 μm.

19. The dye-sensitized solar cell of claim 11, wherein each of the protrusions has a bar-shape.

20. A dye-sensitized solar cell comprising:
a photoelectrode and a counter electrode facing each other;
a semiconductor layer on the photoelectrode and onto which a photosensitive dye excited by light is adsorbed;
a plurality of spacers between the photoelectrode and the counter electrode to maintain a uniform distance between the photoelectrode and the counter electrode; and
an electrolyte filled in a space between the photoelectrode and the counter electrode,
wherein the plurality of spacers have first ends facing and thermally fixed to the counter electrode and second ends facing and non-thermally fixed to the photoelectrode.
